(19) United States
(12) Patent Application Publication
(10) Pub. No.: US 2014/0062274 A1
(43) Pub. Date: Mar. 6, 2014

(54) FIXING MEMBER AND DISPLAY APPARATUS

(71) Applicant: Sony Corporation, Tokyo (JP)

(72) Inventor: Takeaki Hirasawa, Tokyo (JP)

(73) Assignee: SONY CORPORATION, Tokyo (JP)

(21) Appl. No.: 13/970,690

(22) Filed: Aug. 20, 2013

(30) Foreign Application Priority Data
Sep. 4, 2012 (JP) 2012-193794

(51) Int. Cl. H05K 5/02

(52) U.S. Cl. CPC H05K 5/0221
USPC 312/223.1; 403/322.4

(57) ABSTRACT

A fixing member includes a base part that is attached to a first member by an attachment member, and a deformed part, which is elastically deformable with respect to the base part and has an engagement part that is capable of engaging a second member and a pressable part to which a pressing force is applied by the attachment member. The deformed part is elastically deformed, the engagement part engages the second member and the first member is fixed to the second member due to a pressing force being applied to the pressable part by the attachment member when the base part is attached to the first member by the attachment member.

### BACKGROUND

The present disclosure relates to a technical field of a fixing member and a display apparatus. More specifically, the present disclosure relates to a technical field that secures a stable fixed state of a first member with respect to a second member in addition to achieving an improvement in the workability of the fixing work of the first member with respect to the second member by providing an elastically deformable deformed part that has an engagement part that is capable of engaging the second member.

A display that has a display surface on which images are displayed is provided in display apparatuses such as television receivers and personal computers. For example, a diffuser panel, an optical sheet or the like is disposed on a rear surface of the display, and a panel module is configured by the display, diffuser panel, optical sheet and the like.

There are display apparatuses that have a structure in which respective predetermined members (first members) are fixed to other members (second members).

Among this kind of display apparatus, there are types in which the panel module is pressed from the rear against a bezel that is provided as a second member by a back chassis that is provided as a first member, and the panel module is held against the bezel by the back chassis being fixed to the bezel.

In addition, there are other display apparatuses in which for example, a panel module that is provided as a first member is fixed to a bezel that is provided as a second member (for example, refer to Japanese Unexamined Patent Application Publication No. 2011-244257).

In such a display apparatus, the first member is fixed to the second member using a fixing member such as a fixing bracket.

In the display apparatus disclosed in Japanese Unexamined Patent Application Publication No. 2011-244257, the bezel is fixed to a peripheral part of a rear surface of a plate-shaped front surface member, and a plurality of hooks are provided in the bezel. The peripheral part of the panel module is pressed from the rear against the bezel, and the fixing member is supported against the bezel in this state.

The fixing member can slide with respect to the bezel, the plurality of hooks can be engaged with respective parts of the fixing member by sliding the fixing member, and the panel module is held against the bezel by the fixing member. In a state in which this kind of panel module is held against the bezel by the fixing member, the panel module is fixed to the bezel by the fixing member by attaching the fixing member to the panel module with an attachment screw.

### SUMMARY

However, in the display apparatus disclosed in Japanese Unexamined Patent Application Publication No. 2011-244257, in a state in which the fixing member is supported against the bezel, it is necessary to perform the work of sliding the fixing member with respect to the bezel and the work of attaching the fixing member to the panel module with the attachment screw after sliding the fixing member, and there is a problem in that the workability of the fixing work of the panel module to the bezel is poor.

In addition, in a case in which a fixing member is used in the abovementioned work to fix a predetermined member to another member, there are cases in which a load is applied to the fixing member from the predetermined member or the other member when the fixing member is supported against the predetermined member or the other member. In a case in which the load on the fixing member is large, there is a concern that a large force will be necessary when supporting the fixing member against the predetermined member or the other member and thus the workability thereof will be poor.

Furthermore, in a state in which the predetermined member is fixed to the other member by the fixing member, it is necessary to secure a stable fixed state of the predetermined member with respect to the other member using the fixing member.

It is desirable that a fixing member and a display apparatus according to an embodiment of the present disclosure secure a stable fixed state in addition to achieving an improvement in the workability of the fixing work of elastically deforming a deformed part at the time of attaching an attachment member and engaging an engagement part.

According to an embodiment of the present disclosure, there is provided a fixing member which includes a base part that is attached to a first member by an attachment member, and a deformed part, which is elastically deformable with respect to the base part and has an engagement part that is capable of engaging a second member and a pressable part to which a pressing force is applied by the attachment member, in which the deformed part is elastically deformed, the engagement part engages the second member and the first member is fixed to the second member due to a pressing force being applied to the pressable part by the attachment member when the base part is attached to the first member by the attachment member.

Therefore, in the fixing member, the deformed part is elastically deformed and the engagement part engages the second member due to a pressing force being applied to the pressable part by the attachment member.

In the abovementioned fixing member, the base part may be configured by a first surface part that is continuous with the deformed part and a second surface part that is orthogonal to the first surface part, and the second surface part may be attached to the first member by the attachment member.

As a result of the base part being configured by a first surface part that is continuous with the deformed part and a second surface part that is orthogonal to the first surface part, and the second surface part being attached to the first member by the attachment member, a portion in which the deformed part is provided and a portion which is attached to the first member do not interfere with one another.

In the abovementioned fixing member, a screw member may be used as the attachment member, and the deformed part may be elastically deformed by a part of the screw member sliding along the pressable part when the screw member is fastened to the first member.

As a result of a screw member being used as the attachment member, and the deformed part being elastically deformed by a part of the screw member sliding along the pressable part when the screw member is fastened to the first member, the attachment of the attachment member to the first member and the engagement of the engagement part with the second member are performed at the same time as the fastening work of the screw member is performed.

In the abovementioned fixing member, the screw member may be formed from a shaft part that has thread grooves and a head part that is provided at one end of the shaft part in the direction of the shaft, and the deformed part may be elastically deformed by the head part sliding along the pressable part.

As a result of the screw member being formed from a shaft part that has thread grooves and a head part that is provided at one end of the shaft part in the direction of the shaft, and the deformed part being elastically deformed by the head part sliding along the pressable part, the deformed part is elastically deformed by performing the fastening work of the screw member.

In the abovementioned fixing member, the pressable part may function as a lever that releases the engagement of the engagement part with the second member.

As a result of the pressable part functioning as a lever that releases the engagement of the engagement part with the second member, it is possible to release the engagement of the engagement part with the second member through operation of the pressable part.

In the abovementioned fixing member, a tip end part of the pressable part may be provided as a guide part that is inclined with respect to other sections and along which the head part of the screw member slides.

As a result of a tip end part of the pressable part being provided as a guide part that is inclined with respect to other portions and along which the head part of the screw member slides, the head part slides along the pressable part by being guided by the guide part.

According to another embodiment of the present disclosure, there is provided a display apparatus including a panel module that has a display that displays images, a bezel that holds a peripheral part of the panel module, a back chassis that presses the panel module and is pressed against the bezel and a fixing member that fixes the back chassis to the bezel, in which the fixing member includes a base part that is attached to the back chassis by an attachment member and a deformed part, which is elastically deformable with respect to the base part and has an engagement part that is capable of engaging the bezel and a pressable part to which a pressing force is applied by the attachment member, and the deformed part is elastically deformed, the engagement part engages the bezel and the back chassis is fixed to the bezel due to a pressing force being applied to the pressable part by the attachment member when the base part is attached to the back chassis by the attachment member.

Therefore, in the fixing member of the display apparatus, the deformed part is elastically deformed and the engagement part engages the bezel due to a pressing force being applied to the pressable part by the attachment member.

According to still another embodiment of the present disclosure, there is provided a display apparatus including a panel module that has a display that displays images, a bezel that holds a peripheral part of the panel module and a fixing member that fixes a back chassis to the bezel, in which the fixing member includes a base part that is attached to the panel module by an attachment member and a deformed part, which is elastically deformable with respect to the base part and has an engagement part that is capable of engaging the bezel and a pressable part to which a pressing force is applied by the attachment member, and the deformed part is elastically deformed, the engagement part engages the bezel and the panel module is fixed to the bezel due to a pressing force being applied to the pressable part by the attachment member when the base part is attached to the panel module by the attachment member.

Therefore, in the fixing member of the display apparatus of the embodiment, the deformed part is elastically deformed and the engagement part engages the bezel due to a pressing force being applied to the pressable part by the attachment member.

The fixing member according to the embodiment of the present disclosure includes a base part that is attached to a first member by an attachment member, and a deformed part, which is elastically deformable with respect to the base part and has an engagement part that is capable of engaging a second member and a pressable part to which a pressing force is applied by the attachment member, in which the deformed part is elastically deformed, the engagement part engages the second member and the first member is fixed to the second member due to a pressing force being applied to the pressable part by the attachment member when the base part is attached to the first member by the attachment member.

Therefore, since the engagement part is engaged with the second member by the attachment member and the first member is fixed to the second member, it is possible to achieve an improvement in the workability of the fixing work.

In addition, since the engagement part is elastically deformed and engaged with the second member, a sufficient engagement amount of the engagement part with the second member is secured in the fixed state, and it is possible to secure a stable fixed state of the first member with respect to the second member.

According to the embodiment of the present disclosure, the base part is configured by a first surface part that is continuous with the deformed part and a second surface part that is orthogonal to the first surface part, and the second surface part is attached to the first member by the attachment member.

Therefore, due to a portion in which the deformed part is provided and a portion which is attached to the first member being formed independently, it is possible to secure high functionality in the fixing member without portions that have different functions interfering with one another.

According to the embodiment of the present disclosure, a screw member is used as the attachment member, and the deformed part is elastically deformed by a part of the screw member sliding along the pressable part when the screw member is fastened to the first member.

Therefore, the attachment of the screw member to the first member and the engagement of the engagement part with the second member are performed at the same time as the fastening work of the screw member is performed, and it is possible to achieve an improvement in workability and a reduction in the number of parts.

According to the embodiment of the present disclosure, the screw member is formed from a shaft part that has thread grooves and a head part that is provided at one end of the shaft part in the direction of the shaft, and the deformed part is elastically deformed by the head part sliding along the pressable part.

Therefore, it is possible to reliably perform elastic deformation of the deformed part with simple work.

According to the embodiment of the present disclosure, the pressable part functions as a lever that releases the engagement of the engagement part with the second member.

Therefore, it is possible to easily perform detachment work of the fixing member and it is possible to achieve a reduction in the number of parts without having to provide a separate lever solely for release.

According to the embodiment of the present disclosure, a tip end part of the pressable part is provided as a guide part that is inclined with respect to other portions and along which the head part of the screw member slides.

Therefore, the head part of the screw member securely slides along the pressable part by being guided by the guide part, and it is possible to reliably perform elastic deformation due to a pressing force being applied to the pressable part.

The display apparatus according to an embodiment of the present disclosure includes a panel module that has a display that displays images, a bezel that holds a peripheral part of the panel module, a back chassis that presses the panel module and is pressed against the bezel and a fixing member that fixes the back chassis to the bezel, in which the fixing member includes a base part that is attached to the back chassis by an attachment member and a deformed part, which is elastically deformable with respect to the base part and has an engagement part that is capable of engaging the bezel and a pressable part to which a pressing force is applied by the attachment member, and the deformed part is elastically deformed, the engagement part engages the bezel and the back chassis is fixed to the bezel due to a pressing force being applied to the pressable part by the attachment member when the base part is attached to the back chassis by the attachment member.

Therefore, since the engagement part is engaged with the bezel by the attachment member and the back chassis is fixed to the bezel, it is possible to achieve an improvement in the workability of the fixing work.

In addition, since the engagement part is elastically deformed and engaged with the bezel, a sufficient engagement amount of the engagement part with the bezel is secured in the fixed state, and it is possible to secure a stable fixed state of the back chassis with respect to the bezel.

The display apparatus according to the embodiment of the present disclosure includes a panel module that has a display that displays images, a bezel that holds a peripheral part of the panel module and a fixing member that fixes a back chassis to the bezel, in which the fixing member includes a base part that is attached to the panel module by an attachment member and a deformed part, which is elastically deformable with respect to the base part and has an engagement part that is capable of engaging the bezel and a pressable part to which a pressing force is applied by the attachment member, and the deformed part is elastically deformed, the engagement part engages the bezel and the panel module is fixed to the bezel due to a pressing force being applied to the pressable part by the attachment member when the base part is attached to the panel module by the attachment member.

Therefore, since the engagement part is engaged with the bezel by the attachment member and the panel module is fixed to the bezel, it is possible to achieve an improvement in the workability of the fixing work.

In addition, since the engagement part is elastically deformed and engaged with the bezel, a sufficient engagement amount of the engagement part with the bezel is secured in the fixed state, and it is possible to secure a stable fixed state of the panel module with respect to the bezel.

### BRIEF DESCRIPTION OF THE DRAWINGS

FIG. 1 is a perspective view of a display apparatus and along with FIGS. 2 to 26, shows a display apparatus according to embodiments of the present disclosure;

FIG. 2 is a perspective view of the display apparatus shown in a state of being viewed from the opposite side of that of FIG. 1;

FIG. 3 is an exploded perspective view of the display apparatus;

FIG. 4 is an expanded exploded perspective view of a part of the display apparatus;

FIG. 5 is an expanded cross-sectional view of a fixing member;

FIG. 6 is an expanded cross-sectional view of another fixing member;

FIG. 7 is an expanded cross-sectional view that shows a state in which each part is sequentially disposed and along with FIGS. 8 to 13, shows a sequence of fixing work;

FIG. 8 is an expanded cross-sectional view that shows a state in which the bezel is positioned with respect to the panel module and the back chassis is attached to the panel module;

FIG. 9 is an expanded cross-sectional view that shows a state in which the fixing member is inserted into a space between a latching protrusion and an outer peripheral surface part from the rear;

FIG. 10 is an expanded cross-sectional view that shows a state in which the engagement part slides to and past the latching protrusion and is elastically deformed in a direction in which an angle of inclination becomes smaller;

FIG. 11 is an expanded cross-sectional view that shows a state in which the engagement part is separated from the latching protrusion and elastically returned;

FIG. 12 is an expanded cross-sectional view that shows a state in which the shaft part of the attachment member is inserted into a screw insertion hole of the fixing member and screwed into a screw hole of the back chassis;

FIG. 13 is an expanded cross-sectional view that shows a state in which a pressing force is applied to the pressable part by the head part of the attachment member, the deformed part is elastically deformed, and the back chassis is fixed to the bezel by the fixing member;

FIG. 14 is an expanded cross-sectional view that shows a state in which a pressing force is applied to the pressable part by a finger when the fixing member is detached;

FIG. 15 is an expanded cross-sectional view that shows a state in which a pressing force is applied to the pressable part by a rear cover that is used as an attachment member;

FIG. 16 is an expanded cross-sectional view that shows a state in which the deformed part is elastically deformed due to a pressing force being applied to the pressable part by a rear cover that is used as an attachment member;

FIG. 17 is an exploded perspective view that shows a fixing member according to a first modification example;

FIG. 18 is an exploded perspective view that shows a fixing member according to a second modification example;

FIG. 19 is an exploded perspective view that shows a fixing member according to a third modification example;

FIG. 20 is an expanded cross-sectional view that shows a state in which each part is sequentially disposed and along with FIGS. 21 to 25, shows a sequence of fixing work when the fixing member according to the third modification example is used;

FIG. 21 is an expanded cross-sectional view that shows a state in which the bezel is positioned with respect to the panel module and the back chassis is attached to the panel module;

FIG. 22 is an expanded cross-sectional view that shows a state in which the engagement part slides to and past the latching protrusion and is elastically deformed in a direction in which an angle of inclination becomes smaller;

FIG. 23 is an expanded cross-sectional view that shows a state in which the engagement part is separated from the latching protrusion and elastically returned;

FIG. 24 is an expanded cross-sectional view that shows a state in which the shaft part of the attachment member is inserted into a screw insertion hole of the fixing member and screwed into a screw hole of the back chassis;

FIG. 25 is an expanded cross-sectional view that shows a state in which a pressing force is applied to the pressable part by the shaft part of the attachment member, the deformed part is elastically deformed, and the back chassis is fixed to the bezel by the fixing member; and

FIG. 26 is an expanded cross-sectional view that shows a state in which a pressing force is applied to the pressable part by a finger when the fixing member according to the third modification example is detached.

### DETAILED DESCRIPTION OF EMBODIMENTS

Hereinafter, favorable embodiments for achieving the fixing member and a display apparatus of the present disclosure will be described with reference to the appended drawings.

The favorable embodiments shown below are embodiments in which the display apparatus according to an embodiment of the present disclosure is applied to a television receiver that has a flat display panel.

Additionally, the scope of application of the display apparatus according to an embodiment of the present disclosure is not limited to a television receiver that has a flat display panel, and a wide range of application is possible in various display apparatuses such as various other television receivers and monitors which are used in personal computers and the like regardless of the type of display.

In addition, the favorable embodiments shown below are embodiments in which the fixing member according to an embodiment of the present disclosure is applied to a fixing member that fixes a back chassis or a panel module to a bezel provided in a television receiver that has a flat display panel.

Additionally, the scope of application of the fixing member according to an embodiment of the present disclosure is not limited to a fixing member that fixes a back chassis or a panel module to a bezel provided in a television receiver that has a flat display panel, and a wide range of application is possible in fixing members that fix a first member to a second member in various structures of various display apparatuses and other electrical appliances such as various other television receivers and monitors which are used in personal computers and the like regardless of the type of display.

### Configuration of Display Apparatus

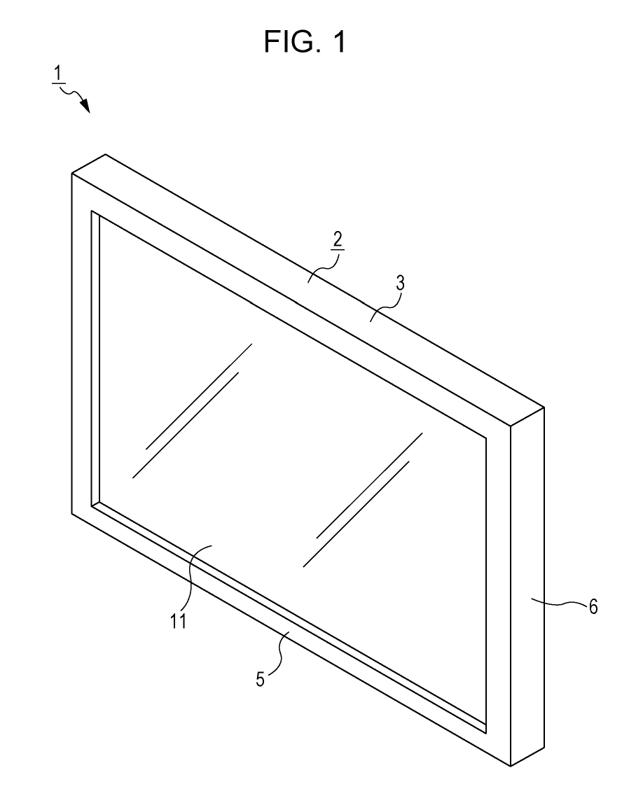

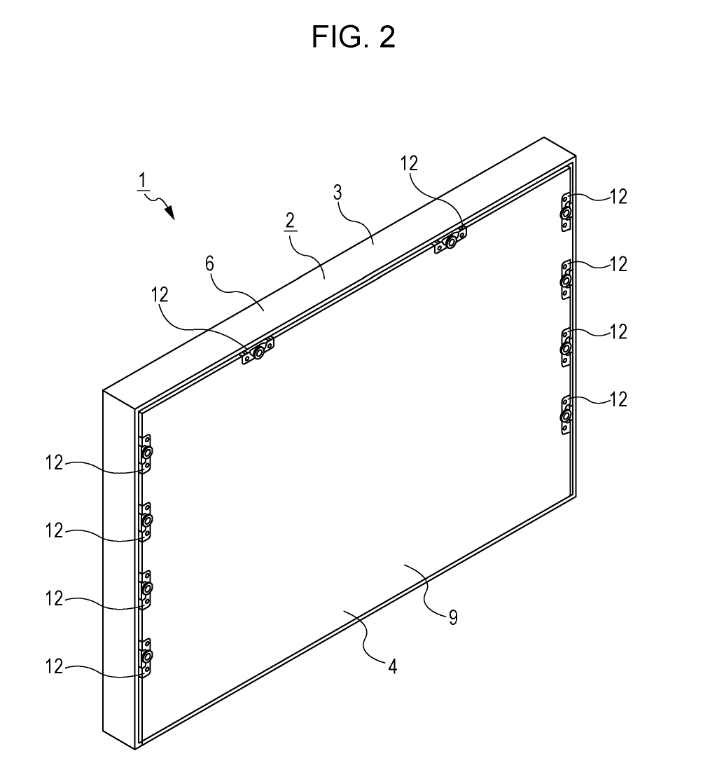

A display apparatus (television receiver) 1 is for example, formed in a substantially wide, flat rectangular shape, and each of the necessary parts thereof are disposed in a housing 2 (refer to FIGS. 1 and 2). The display apparatus 1 is for example, held by a stand that is not shown in the drawings.

The housing 2 has a bezel 3 that is disposed on the front side thereof, a back chassis 4 that is disposed on the back side thereof, and a rear cover (not shown in the drawings) that is attached to a rear surface side of the back chassis 4.

The bezel 3 is formed in a substantially rectangular frame shape. Additionally, the bezel 3 may have a configuration of being provided as four members with the upper, lower, left and right sides being independent from one another in which a frame shape is formed by combining the four members, or the entirety thereof may be formed integrally.

The bezel 3 has a front surface part 5 and a peripheral surface part 6 (refer to FIGS. 1 to 3).

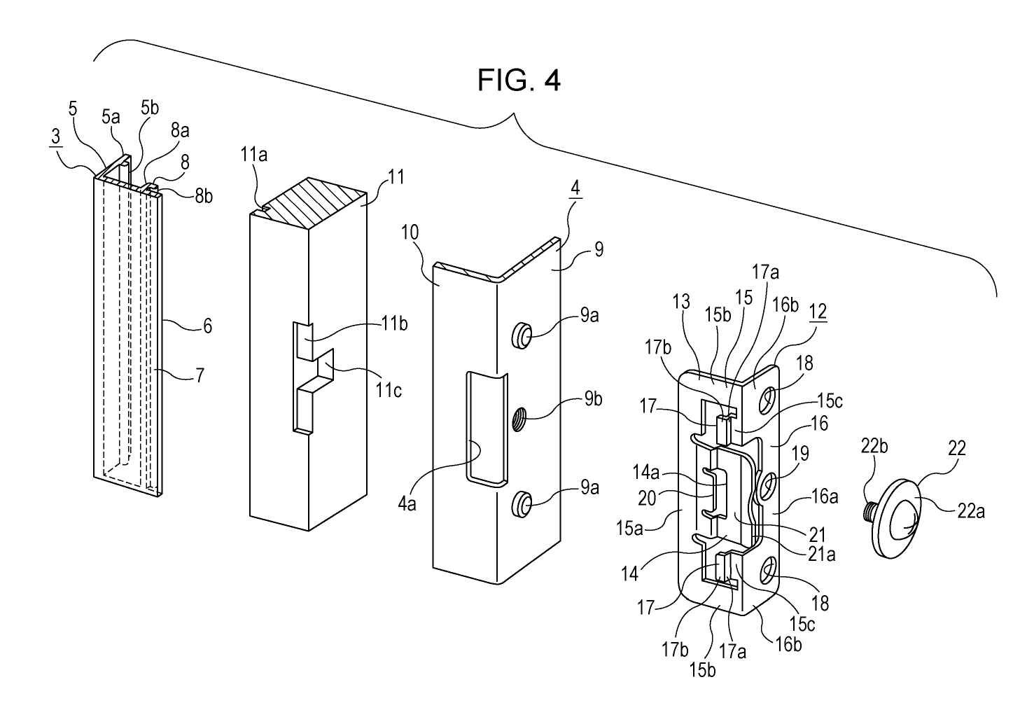

The front surface part 5 has a pressing surface part 5a that faces a posterior-anterior direction and a positioning protrusion 5b that protrudes rearward from a position that is close to the inner periphery of the pressing surface part 5a (refer to FIG. 4).

The peripheral surface part 6 has a holding surface part 7 that protrudes rearward from a peripheral part of the pressing surface part 5a and a latching protrusion 8 that protrudes inward from a position that is close to the rear end of the holding surface part 7. The latching protrusion 8 is formed from a root part 8a that faces a posterior-anterior direction and a latching part 8b that protrudes rearward from an inner peripheral part of the root part 8a. The rear end of the latching part 8b is positioned on a front side close to the rear end of the peripheral surface part 6.

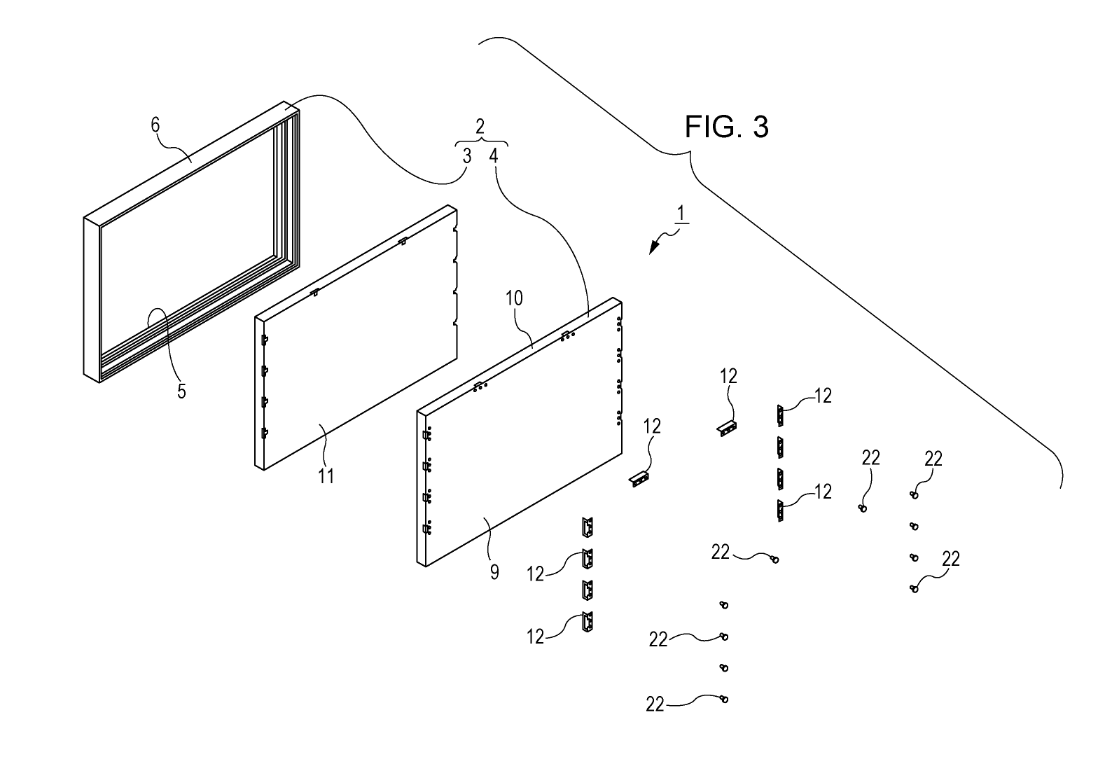

The back chassis 4 has a base surface part 9 that is formed in a wide shape that faces a posterior-anterior direction and an outer peripheral surface part 10 that protrudes forward from an outer peripheral edge of the base surface part 9 (refer to FIGS. 3 and 4). Additionally, there are cases in which the back chassis 4 has a configuration of being included in a panel module (to be described later), but the display apparatus 1 is described as a configuration in which the back chassis 4 and the panel module are separate.

Positioning protruding parts 9a, 9a, . . . that protrude rearward are provided at the peripheral part of the base surface part 9 spaced in a circumferential direction (refer to FIG. 4). A screw hole 9b is formed at the peripheral part of the base surface part 9 and between positioning protruding parts 9a and 9a.

A relief hole 4a is formed in a portion in which the base surface part 9 and the outer peripheral surface part 10 of the back chassis 4 are continuous.

A panel module 11 is disposed in an inner part of the housing 2, and, as will be described later, the panel module 11 is held against the bezel 3 by the back chassis 4 being fixed to the bezel 3. The back chassis 4 is a first member that is fixed to the bezel 3 and the bezel 3 is a second member that is fixed to the back chassis 4.

The panel module 11 is formed by a diffuser panel that diffuses a display on which images are displayed and light that is incident to the display, a plurality of optical sheets that respectively fulfill predetermined functions with respect to light that is incident to the display, a light source that functions as a backlight, a light guide plate that leads light in a predetermined direction, a holding bracket and the like being disposed. Additionally, the panel module 11 is simply shown as one member in the respective drawings.

A positioning groove 11a that extends in the circumferential direction is formed at the peripheral part of the front surface of the panel module 11. A shallow first relief concave part 11b that opens outward and a second relief concave part 11c that opens toward the rear are formed in a communicative state in a continuous portion of the outer peripheral surface and the rear surface of the panel module 11.

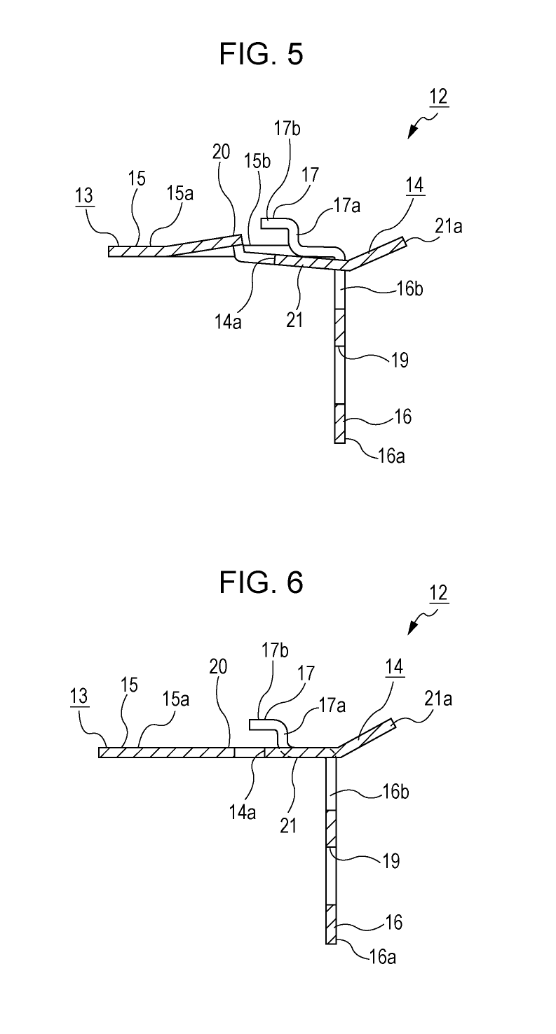

The back chassis 4 is fixed to the bezel 3 by fixing members 12, 12, . . . . The fixing members 12 are formed from a plate-shape metal material or resin material being formed into a predetermined shape, and have for example, a base part 13 and a deformed part 14 which is elastically deformable with respect to the base part 13 (refer to FIGS. 4 and 5).

The base part 13 is formed from a first surface part 15 and a second surface part 16 and is formed to be bent so that the first surface part 15 and the second surface part 16 are orthogonal.

The first surface part 15 is formed from a long side part 15a that extends in the horizontal direction or the vertical direction, short piece parts 15b and 15b that respectively protrude rearward from both end parts in the longitudinal direction of the long side part 15a, and protruding portions 15c and 15c that protrude from the rear end parts of the short piece parts 15b and 15b in directions in which the protruding portions 15c and 15c approach one another.

Holding piece parts 17 and 17 are provided in the base part 13. The holding piece parts 17 are provided continuously on the front end of a protruding portion 16c, and are formed from a standing bent part 17a that protrudes outward from the protruding portions 16c and a holding protrusion part 17b that protrudes forward from the outer end part of the rising bent part 17a.

The second surface part 16 is formed from a longitudinal part 16a that extends in the horizontal direction or the vertical direction, and short end parts 16b and 16b that respectively protrude outward from both end parts in the longitudinal direction of the longitudinal part 16a, and the short end parts 16b and 16b are respectively continuous with the short piece parts 15b and 15b and the protruding portions 15c and 15c of the first surface part 15.

Positioning holes 18 and 18 are formed in the longitudinal part 16a spaced in the longitudinal direction, and a screw insertion hole 19 is formed between the positioning holes 18 and 18.

The deformed part 14 is continuous with a central part of the long side part 15a of the first surface part 15 in the longitudinal direction, and protrudes rearward from the long side part 15a. The deformed part 14 is disposed between the holding piece parts 17 and 17.

An inverse C-shaped notch 14a that opens toward the front is formed in the deformed part 14 in a portion that is close to the long side part 15a, and a portion that is surrounded by the notch 14a is provided as an engagement part 20. The engagement part 20 is partially inclined so as to become displaced outward with movement toward the tip thereof (refer to FIG. 5). Additionally, the engagement part 20 may be positioned in a planar form in the same manner as the first surface part 15 without being inclined (refer to FIG. 6).

In the deformed part 14, a portion other than the engagement part 20 is provided as a pressable part 21 (refer to FIGS. 4 and 5). A front end part of the pressable part 21 is provided as a guide part 21a, and the guide part 21a is inclined so as to become displaced outward with movement toward the rear thereof.

### Fixing Work of Back Chassis to Bezel

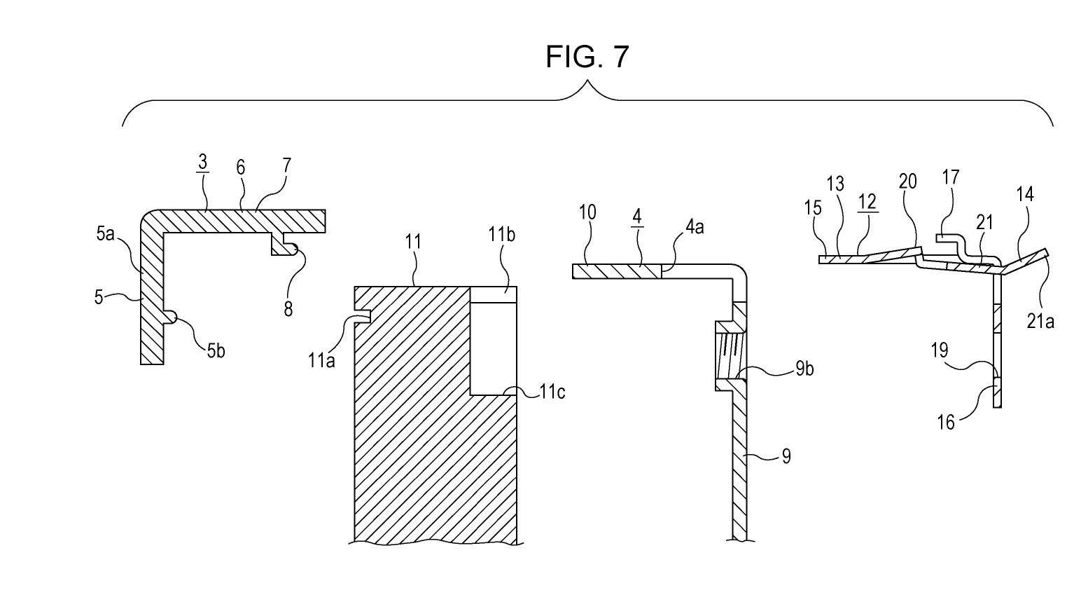

Next, fixing work of the back chassis 4 that is provided as a first member to the bezel 3 that is provided as a second member will be described (refer to FIGS. 7 to 13).

An attachment member 22 is used in the fixing work of the back chassis 4 to the bezel 3, and for example, a screw member may be used as the attachment member 22. The screw member that is used as the attachment member 22 is formed from a head part 22a and a shaft part 22b that has thread grooves (refer to FIG. 4).

In the fixing work, the bezel 3, the panel module 11, the back chassis 4 and the fixing members 12, 12, . . . are sequentially disposed from the front side (refer to FIG. 7).

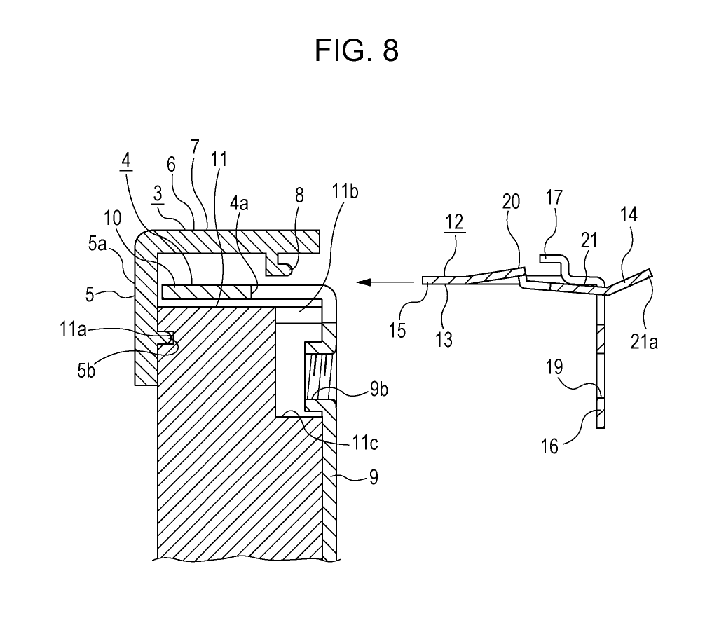

Next, the bezel 3 is positioned with respect to the panel module 11 by inserting the positioning protrusion 5b of the bezel 3 into the positioning groove 11a of the panel module 11 (refer to FIG. 8). At this time, the back chassis 4 is attached to the panel module 11 from the rear, the base surface part 9 is pressed against the panel module 11 from the rear, and the outer peripheral surface part 10 is positioned inside the peripheral surface part 6 of the bezel 3 over the outside of the outer peripheral surface of the panel module 11.

In a state in which the bezel 3 is positioned with respect to the panel module 11 and the back chassis 4 is attached to the panel module 11 in the abovementioned manner, a space is formed between the latching protrusion 8 of the bezel 3 and the outer peripheral surface part 10 of the back chassis 4. In addition, the relief hole 4a of the back chassis 4 is positioned corresponding to the first relief concave part 11b of the panel module 11, and the screw hole 9b of the back chassis 4 is positioned corresponding to the second relief concave part 11c of the panel module 11.

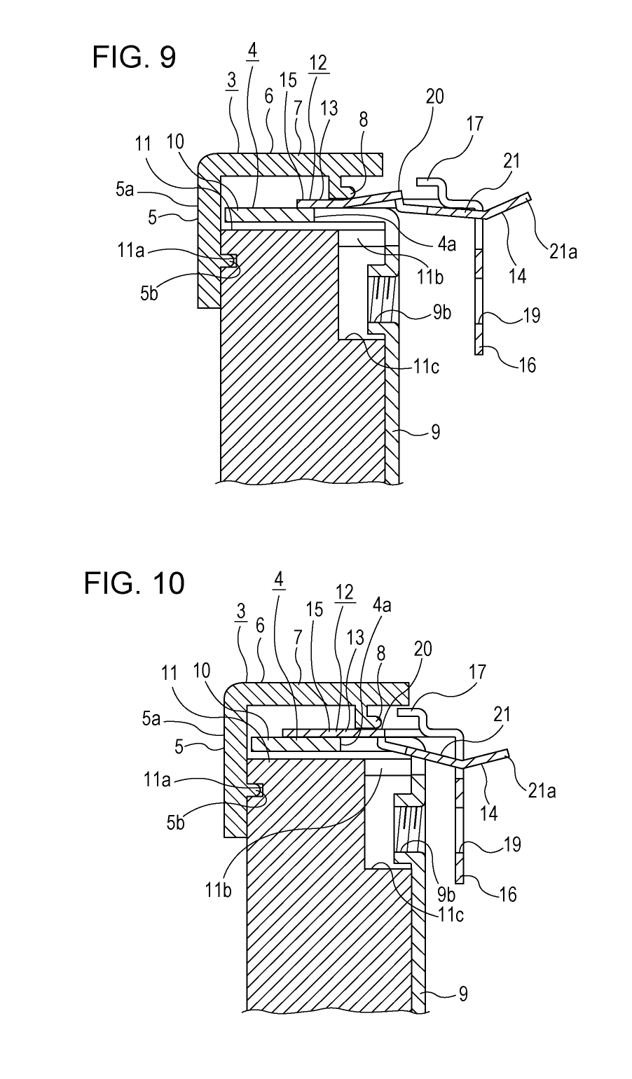

Next, the first surface part 15 and the deformed part 14 of the fixing member 12 are inserted into a space between the latching protrusion 8 and the outer peripheral surface part 10 (refer to FIG. 9). At this time, in a case in which the engagement part 20 is inclined, the engagement part slides to and past the latching protrusion 8 and is elastically deformed in a direction in which the angle of inclination thereof with respect to the first surface part 15 becomes smaller (refer to FIG. 10).

Additionally, at this time, in a case in which a fixing member 12 in which the engagement part 20 is not inclined is being used (refer to FIG. 6), since the engagement part 20 does not slide to the latching protrusion 8, a load from the bezel 3 with respect to the insertion of the fixing member 12 is not applied, it is possible to secure smooth insertion of the fixing member 12, and it is possible to secure high workability in the fixing work.

The pressable part 21 is also elastically deformed in a direction in which the pressable part approaches the panel module 11 when the engagement part 20 is elastically deformed, but since the relief hole 4a is formed in the back chassis 4 and the first relief concave part 11b is formed in the panel module 11, the pressable part 21 is inserted into the relief hole 4a and the first relief concave part 11b.

Therefore, since the pressable part 21 does not come into contact with the back chassis 4 or the panel module 11, the deformation of the pressable part 21 is not blocked and it is possible to achieve an improvement in workability.

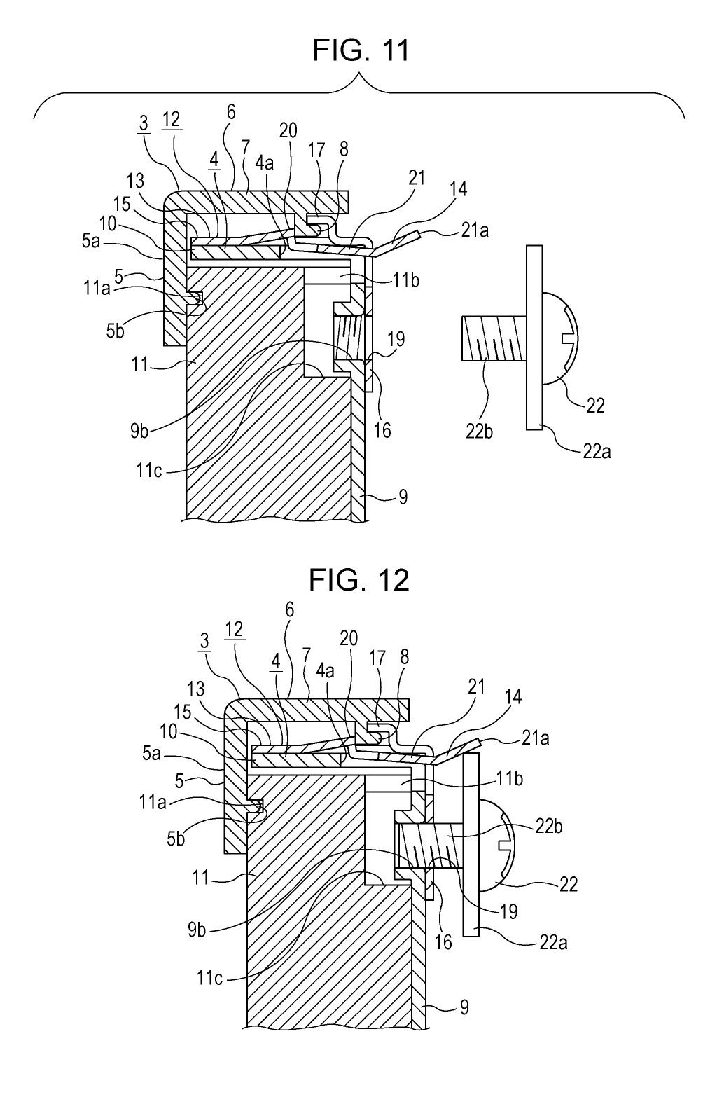

As the fixing member 12 is inserted further into the space, the engagement part 20 is separated from the latching protrusion 8 and elastically returned, and the engagement part 20 is positioned on the front side of the latching protrusion 8 (refer to FIG. 11). At this time, the tip of the engagement part 20 latches onto a front surface of the tip end part of the root part 8a of the latching protrusion 8. When the fixing member 12 is inserted into the space and the engagement part 20 is positioned on the front side of the latching protrusion 8, the positioning protruding parts 9a and 9a of the back chassis 4 are respectively inserted into the positioning holes 18 and 18 of the fixing member 12 inserted into, and positioning of the fixing member 12 with respect to the back chassis 4 is performed.

In addition, at the same time, the holding piece parts 17 and 17 of the fixing member 12 are latched onto the latching part 8b of the latching protrusion 8 of the bezel 3 from the outside, and uplift of the back chassis 4 from the panel module 11 is prevented.

Next, the shaft part 22b of the attachment member 22 is inserted into the screw insertion hole 19 of the fixing member 12 and screwed into the screw hole 9b of the back chassis 4 (refer to FIG. 12). At this time, the peripheral part of the head part 22a of the attachment member 22 slides along the guide part 21a of the pressable part 21 of the fixing member 12 (refer to FIG. 12).

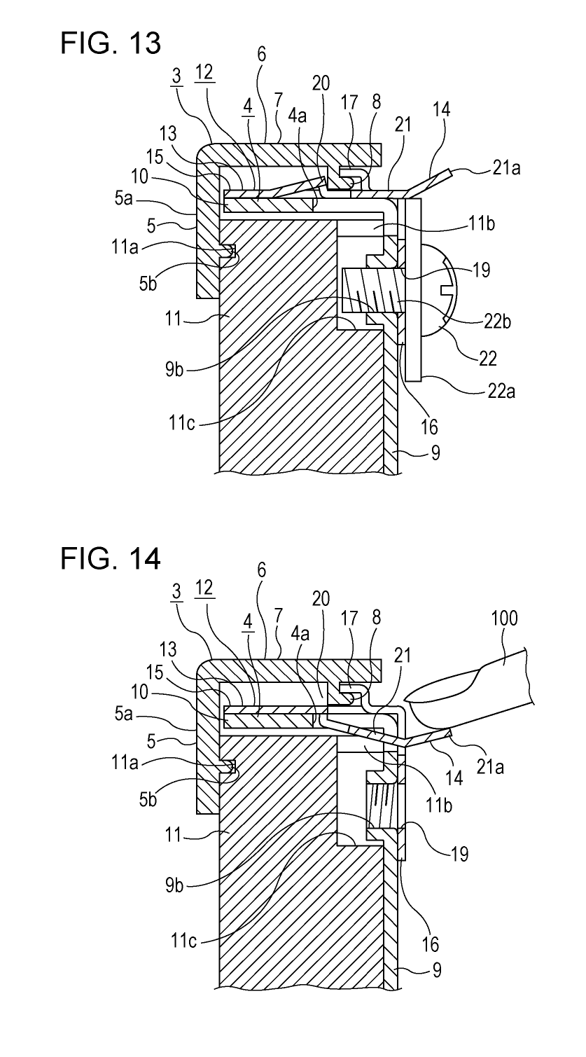

Furthermore, as the shaft part 22b of the attachment member 22 is screwed into the screw hole 9b, a pressing force is applied to the pressable part 21 in a direction in which the pressable part 21 approaches the peripheral surface part 6 of the bezel 3 by the head part 22a of the attachment member 22, and the deformed part 14 is elastically deformed with respect to the base part 13 (refer to FIG. 13). Additionally, since the shaft part 22b that is screwed into the screw hole 9b is inserted into the second relief concave part 11c of the panel module 11 from the screw hole 9b, contact between the shaft part 22b and the panel module 11 is avoided.

In the manner described above, since the guide part 21a that is inclined with respect to other portions in the pressable part 21 of the fixing member 12, the head part 22a securely slides along the pressable part 21 by being guided by the guide part 21a, and it is possible to reliably perform elastic deformation of the pressable part 21 due to a pressing force being applied to the pressable part 21.

The engagement part 20 is deformed due to the deformed part 14 being elastically deformed and is engaged with the latching protrusion 8 of the bezel 3. Therefore, a state in which dropout of the fixing member 12 from the bezel 3 is prevented, is attained, and at the same time, the fixing member 12 is attached to the back chassis 4 by the attachment member 22, and the back chassis 4 is fixed to the bezel 3 by the fixing member 12.

In the manner described above, the fixing member 12 is configured by the first surface part 15 in which the base part 13 is continuous with the deformed part 14 and the second surface part 16 that is orthogonal to the first surface part 15, and the second surface part 16 is attached to the back chassis 4, which is the first member, by the attachment member 22.

Therefore, in the fixing member 12, by forming a portion (the first surface part 15) in which the deformed part is provided and a portion (the second surface part 16) which is attached to the back chassis 4 independently, it is possible to secure high functionality in the fixing member 12 without portions that have different functions interfering with one another.

In addition, when the screw member is used as the attachment member 22, and the attachment member 22 is attached to the back chassis 4, the attachment member 22 slides along the pressable part 21 and the pressable part 21 is elastically deformed.

Therefore, the attachment of the attachment member 22 to the back chassis 4 and the engagement of the engagement part 20 with the bezel 3 are performed at the same time as the fastening work of the attachment member 22 is performed, and it is possible to achieve an improvement in workability and a reduction in the number of parts.

Furthermore, since the deformed part 14 is elastically deformed by the head part 22a of the screw member, which is provided as the attachment member 22, sliding along the pressable part 21, the deformed part 14 is elastically deformed by performing the fastening work of the attachment member 22 and it is possible to reliably perform elastic deformation of the deformed part 14 with simple work.

Additionally, in the display apparatus 1, in a case in which maintenance of each part or the like is being performed, there are cases in which it is necessary for the fixing member 12 to be detached from the back chassis 4 and the bezel 3. In such cases, a pressing force is applied to the pressable part 21 in a direction in which the pressable part 21 approaches the panel module 11 by a finger 100 in a state in which the attachment member 22 is detached from the back chassis 4 (refer to FIG. 14). By applying a pressing force to the pressable part 21 in a direction in which the pressable part 21 approaches the panel module 11 with a finger 100, the engaged state of the engagement part 20 with respect to the latching protrusion 8 is released, and it is possible to detach the fixing member 12 from a space between the latching protrusion 8 and the outer peripheral surface part 10 by drawing the fixing member 12 out toward the rear.

In this manner, since the pressable part 21 functions as a lever when performing release of the engagement part 20 with respect to the bezel 3, it is possible to easily perform detachment work of the fixing member 12 and it is possible to achieve a reduction in the number of parts without having to provide a separate lever solely for release.

Additionally, in the abovementioned description, an example in which a screw member is used as the attachment member 22 is shown, but the attachment member is not limited to a screw member, and for example, a rear cover which is attached to the rear surface side of the back chassis 4 may be used as an attachment member 22A.

In a case in which a rear cover is used as the attachment member 22A, the second surface part 16 of the fixing member 12 is attached to the base surface part 9 of the back chassis 4 by an attachment screw 200 or the like in advance.

Additionally, it is possible for the second surface part 16 of the fixing member 12 not to be attached to the back chassis 4 by an attachment screw 200 or the like in advance, and for example, a configuration in which attachment is performed by pressing the second surface part 16 against the back chassis 4 with the rear cover when the rear cover is attached to the rear surface side of the back chassis 4 in a state of being supported by the back chassis 4, may be used.

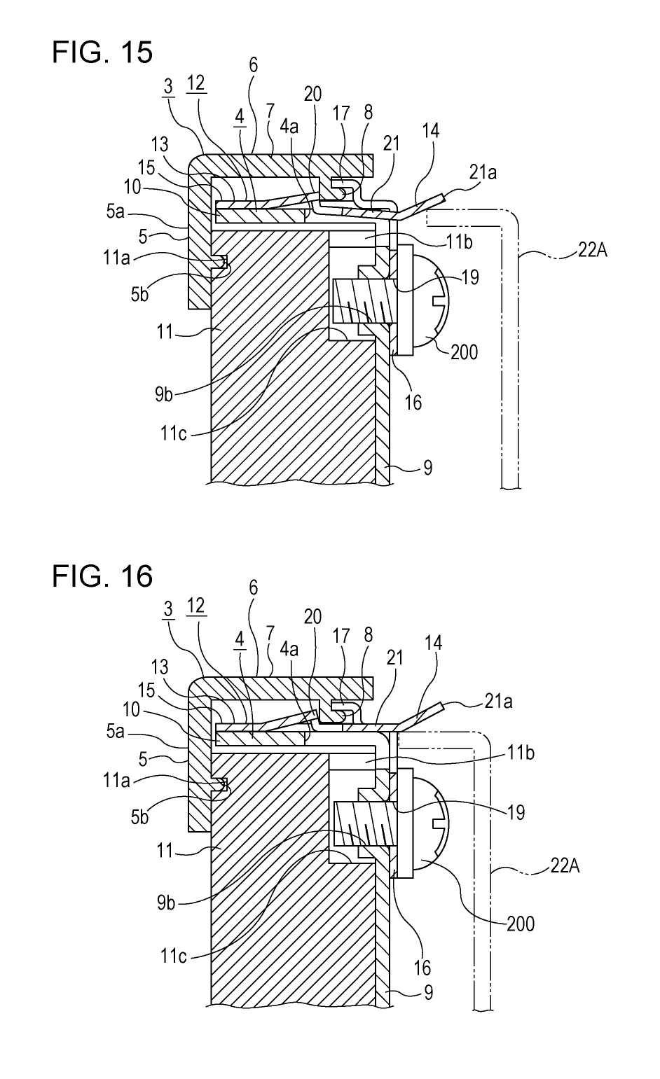

When the attachment member (the rear cover) 22A is attached to the rear surface side of the back chassis 4, a pressing force is applied to the pressable part 21 of the fixing member 12 by the attachment member 22A, and the deformed part 14 is elastically deformed with respect to the base part 13 (refer to FIG. 15).

The engagement part 20 is deformed due to the deformed part 14 being elastically deformed, and is engaged with the latching protrusion 8 of the bezel 3. Therefore, a state in which dropout of the fixing member 12 from the bezel 3 is prevented, is attained, and the back chassis 4 is fixed to the bezel 3 by the fixing member 12 (refer to FIG. 16).

### MODIFICATION EXAMPLE

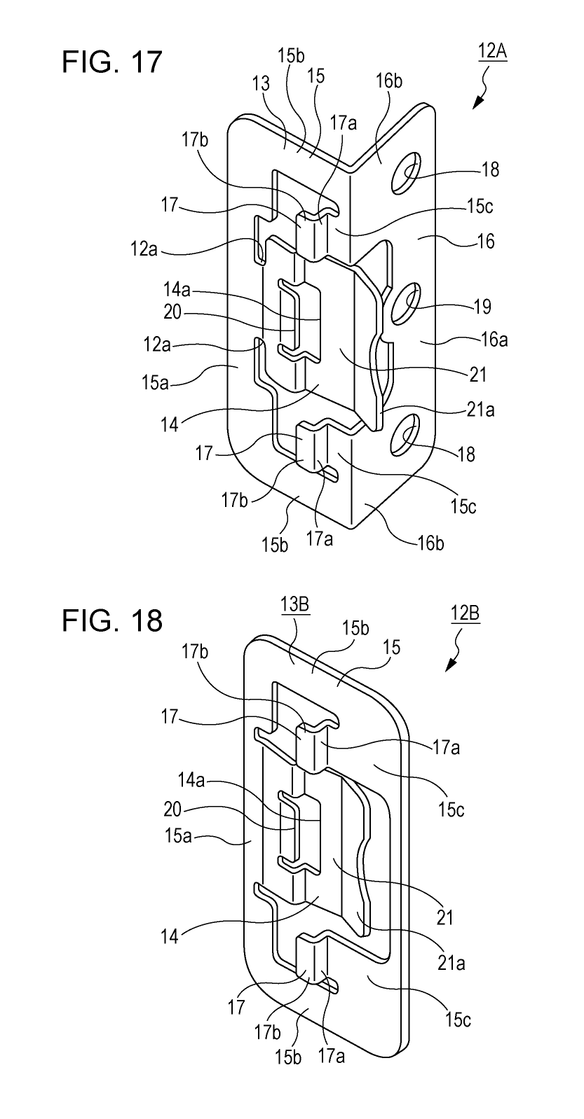

Hereinafter, modification examples of the fixing member will be described (refer to FIGS. 17 to 23).

### First Modification Example

Firstly, a first modification example will be described (refer to FIG. 17).

Additionally, in comparison with the abovementioned fixing member 12, a fixing member 12A according to the first modification example that is shown below only differs in that the size of a continuous portion of the first surface part of the base part and the deformed part is smaller. Therefore, detailed description is only given for portions of the fixing member 12A according to the first modification example that differ in comparison with the fixing member 12, and the same reference symbols are given to portions which are the same as those of the fixing member 12 and description thereof is omitted.

In the fixing member 12A according to the first modification example, slits 12a and 12a are formed between the first surface part 15 of a base part 13A and the deformed part 14 spaced in the longitudinal direction of the long side part 15a.

Therefore, the size (length) of the continuous portion of the first surface part 15 and the deformed part 14 is smaller than that of the fixing member 12.

In such a fixing member 12A, since the size of the continuous portion of the first surface part 15 and the deformed part 14 is smaller, the deformed part 14 is easily elastically deformed with respect to the base part 13A, and it is possible to easily perform the attachment work of the attachment member 22 with little force.

Additionally, it is possible to arbitrarily set the size of the continuous portion of the first surface part 15 and the deformed part 14, and by arbitrarily setting the size of the continuous portion, it is possible to arbitrarily control the ease of the elastic deformation of the deformed part 14 with respect to the base part 13A.

In addition, it is also possible to arbitrarily set the positions of the slits 12a and 12a in the posterior-anterior direction, and by arbitrarily setting the positions of the slits 12a and 12a in the posterior-anterior direction, it is possible to arbitrarily control the length of the deformed part 14 in the posterior-anterior direction in addition to the angle of deformation and amount of deformation of the deformed part 14.

### Second Modification Example

Next, a second modification example will be described (refer to FIG. 18).

Additionally, in comparison with the abovementioned fixing member 12, a fixing member 12B according to the second modification example that is shown below only differs in that the second surface part of the base part is not provided. Therefore, detailed description is only given for portions of the fixing member 12B according to the second modification example that differ in comparison with the fixing member 12, and the same reference symbols are given to portions which are the same as those of the fixing member 12 and description thereof is omitted.

In the fixing member 12B according to the second modification example, the second surface part 16 of a base part 13B is not provided and the base part 13B is formed in a plate shape by the first surface part 15 only.

In such a fixing member 12B, since the base part 13B is formed in a plate shape by the first surface part 15 only, the configuration is simple, processing is easy and it is possible to achieve a reduction in the production cost thereof.

Additionally, in a case in which the fixing member 12B is used, in the fixing member 12B, a pressing force is applied to the pressable part 21 of the fixing member 12B by an attachment member such as the rear cover in a state in which the base part 13B is attached to the back chassis 4 in advance by an attachment screw, a latch, adhesion or the like, the deformed part 14 is elastically deformed with respect to the base part 13B and the back chassis 4 is fixed to the bezel 3 by the fixing member 12B.

Additionally, in the fixing member 12B, the base part 13B may not be attached to the back chassis 4 in advance by an attachment screw or the like, and for example, a configuration in which attachment is performed by pressing the second surface part 16 against the back chassis 4 with the rear cover when the rear cover which functions as an attachment member is attached to the rear surface side of the back chassis 4 in a state of being supported by the back chassis 4, may be used.

### Third Modification Example

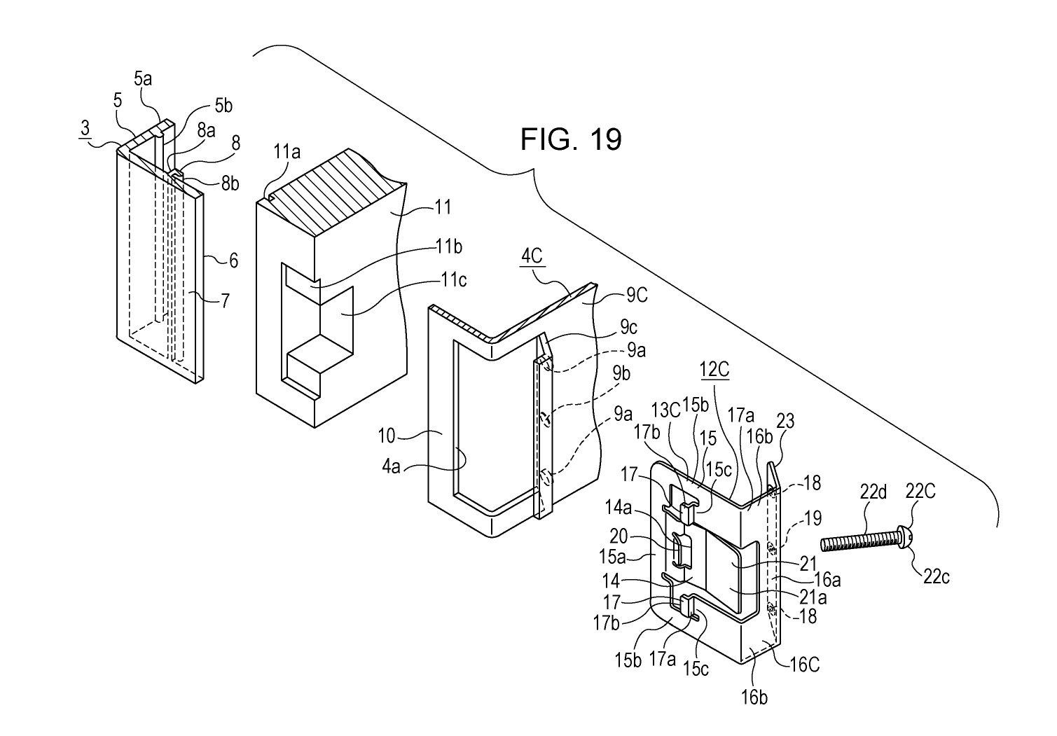

Next, a third modification example will be described (refer to FIGS. 19 to 26).

Additionally, in comparison with the abovementioned fixing member 12, a fixing member 12C according to the third modification example that is shown below only differs in that the shape and configuration of portions other than the first surface part of the base part are different. Therefore, detailed description is only given for portions of the fixing member 12C according to the third modification example that differ in comparison with those of the fixing member 12, and the same reference symbols are given to portions which are the same as those of the fixing member 12 and description thereof is omitted.

In addition, in a case in which the fixing member 12C according to the third modification example is used, since the shape of the back chassis is different, the back chassis will be described.

A back chassis 4C has a base surface part 9C that is formed in a wide shape that faces a posterior-anterior direction and an outer peripheral surface part 10 that protrudes forward from an outer peripheral edge of the base surface part 9C (refer to FIG. 19).

An attachment surface part 9c, a part of which is formed to be bent toward the outside is provided at the peripheral part of the base surface part 9C. The attachment surface part 9c protrudes in a diagonally rearward direction.

Positioning protruding parts 9a, 9a, . . . are provided in the attachment surface part 9c, and a screw hole 9b is formed between positioning protruding parts 9a and 9a.

The fixing member 12C is formed from a plate-shape metal material or resin material being formed into a predetermined shape, and has for example, a base part 13C and a deformed part 14 which is elastically deformable with respect to the base part 13C.

The base part 13C is formed from a first surface part 15, a second surface part 16C and a third surface part 23, is formed to be bent so that the first surface part 15 and the second surface part 16C are orthogonal, and is formed to be bent toward a direction in which the base part 13C approaches the first surface part 15 so that the third surface part 23 is inclined with respect to the second surface part 16C.

The second surface part 16C is formed from a longitudinal part 16a that extends in the horizontal direction or the vertical direction, and short end parts 16b and 16b that respectively protrude outward from both end parts in the longitudinal direction of the longitudinal part 16a, and the short end parts 16b and 16b are respectively continuous with the short piece parts 15b and 15b and the protruding portions 15c and 15c of the first surface part 15.

Positioning holes 18 and 18 are formed in the third surface part 23 spaced in the longitudinal direction, and a screw insertion hole 19 is formed between the positioning holes 18 and 18.

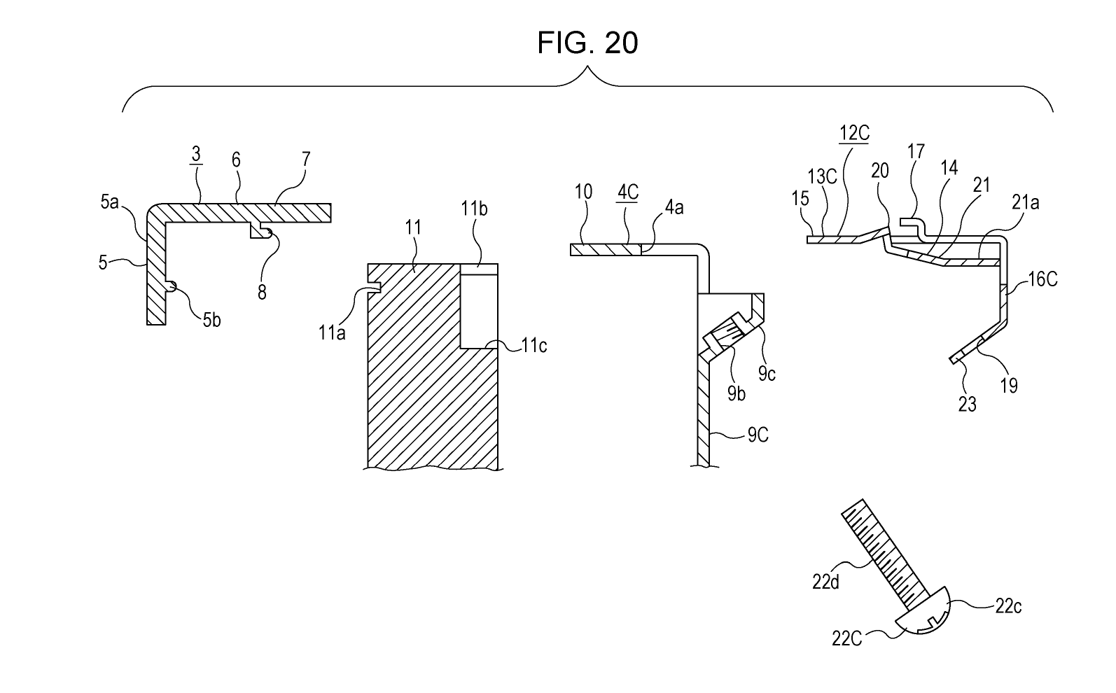

Hereinafter, fixing work of the back chassis 4C to the bezel 3 using the fixing member 12C will be described (refer to FIGS. 20 to 25).

An attachment member 22C is used in the fixing work of the back chassis 4C to the bezel 3, and for example, a screw member may be used as the attachment member 22C (refer to FIGS. 19 and 20). The screw member that is used as the attachment member 22C is formed from a head part 22c and a shaft part 22d that has thread grooves. Additionally, in comparison with the attachment member 22, the external diameter of the head part 22c of the attachment member 22C is smaller than the external diameter of the head part 22a.

In the fixing work, the bezel 3, the panel module 11, the back chassis 4C and the fixing members 12C, 12C, . . . are sequentially disposed from the front side (refer to FIG. 20).

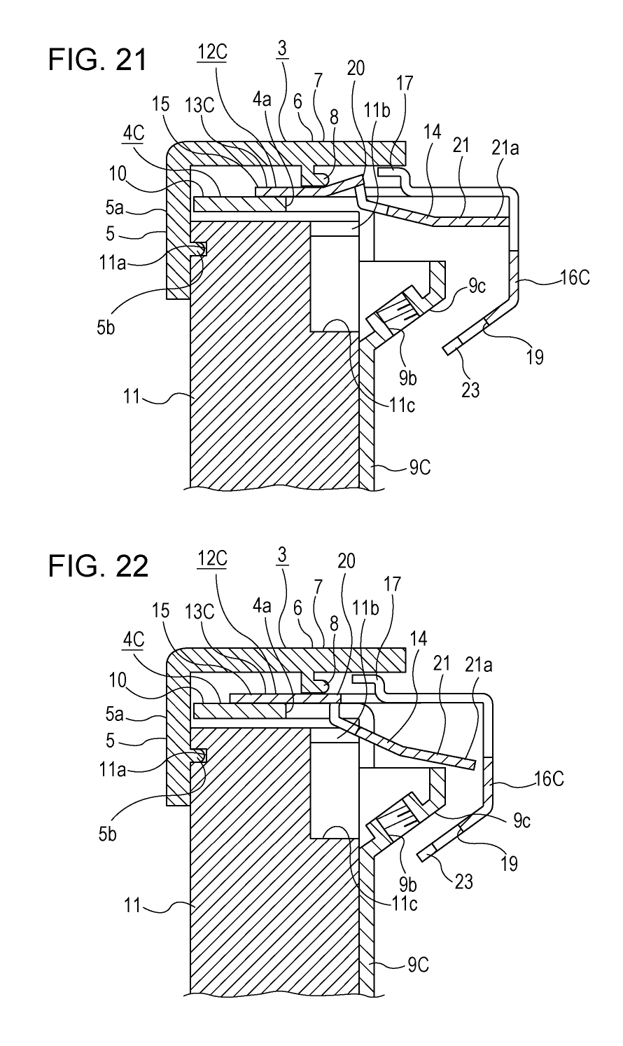

Next, the bezel 3 is positioned with respect to the panel module 11 by the positioning protrusion 5b of the bezel 3 being inserted into the positioning groove 11a of the panel module 11 (refer to FIG. 21). At this time, the back chassis 4C is attached to the panel module 11 from the rear, the base surface part 9C is pressed against the panel module 11 from the rear, and the outer peripheral surface part 10 is positioned inside the peripheral surface part 6 of the bezel 3 over the outside of the outer peripheral surface of the panel module 11.

In a state in which the bezel 3 is positioned with respect to the panel module 11 and the back chassis 4C is attached to the panel module 11 in the abovementioned manner, a space is formed between the latching protrusion 8 of the bezel 3 and the outer peripheral surface part 10 of the back chassis 4C. In addition, the relief hole 4a of the back chassis 4C is positioned corresponding to the first relief concave part 11b of the panel module 11, and the screw hole 9b of the back chassis 4C is positioned corresponding to the second relief concave part 11c of the panel module 11.

Next, the first surface part 15 and the deformed part 14 of the fixing member 12C are inserted into a space between the latching protrusion 8 and the outer peripheral surface part 10 (refer to FIG. 21). At this time, in a case in which the engagement part 20 is inclined, the engagement part 20 slides to and past the latching protrusion 8 and is elastically deformed in a direction in which the angle of inclination thereof with respect to the first surface part 15 becomes smaller (refer to FIG. 22).

Additionally, at this time, in a case in which a fixing member 12 in which the engagement part 20 is not inclined is being used, since the engagement part 20 does not slide to the latching protrusion 8, a load from the bezel 3 with respect to the insertion of the fixing member 12 is not applied, it is possible to secure smooth insertion of the fixing member 12, and it is possible to secure high workability in the fixing work.

The pressable part 21 is also elastically deformed in a direction which approaches the panel module 11 when the engagement part 20 is elastically deformed, but since the relief hole 4a is formed in the back chassis 4C and the first relief concave part 11b is formed in the panel module 11, the pressable part 21 is inserted into the relief hole 4a and the first relief concave part 11b.

Therefore, since the pressable part 21 does not come into contact with the back chassis 4C or the panel module 11, the deformation of the pressable part 21 is not blocked and it is possible to achieve an improvement in workability.

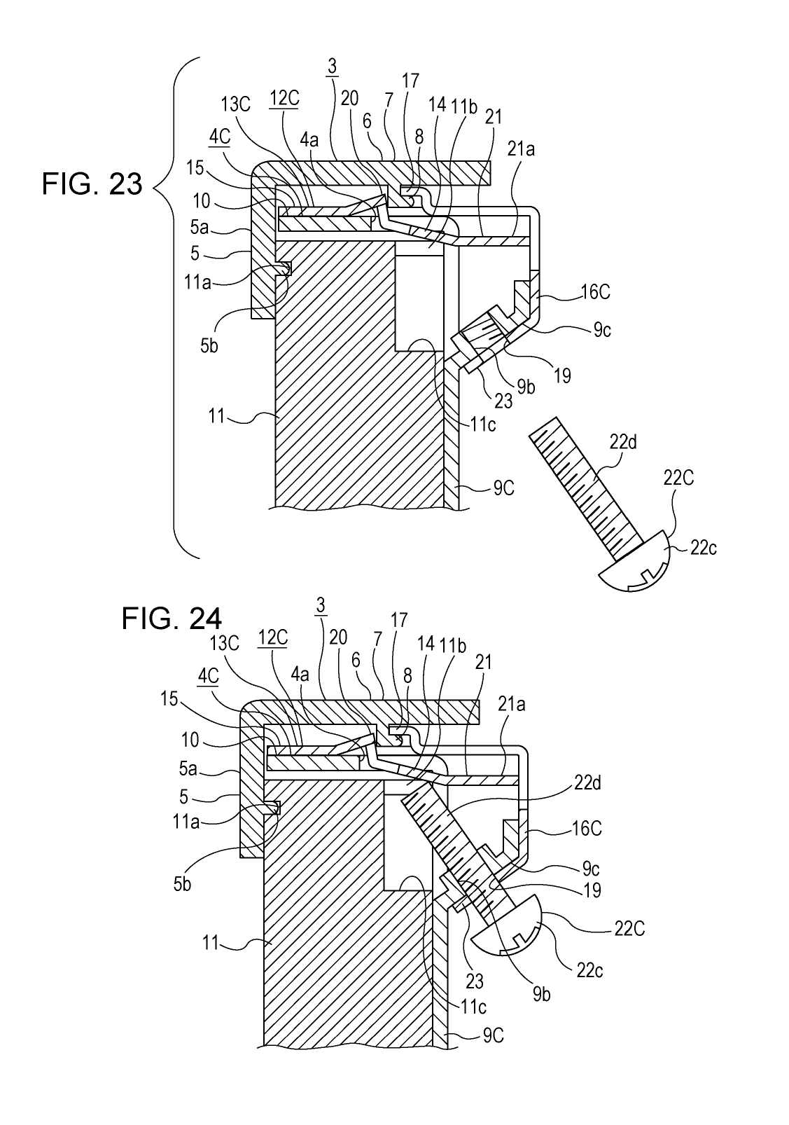

As the fixing member 12C is inserted further into the space, the engagement part 20 is separated from the latching protrusion 8 and elastically returned, and the engagement part 20 is positioned on the front side of the latching protrusion 8 (refer to FIG. 23). At this time, the tip of the engagement part 20 latches onto a front surface of the tip end part of the root part 8a of the latching protrusion 8. When the fixing member 12C is inserted into the space and the engagement part 20 is positioned on the front side of the latching protrusion 8, the positioning holes 18 and 18 of the fixing member 12C are respectively inserted into the positioning protruding parts 9a and 9a of the back chassis 4C, and positioning of the fixing member 12C with respect to the back chassis 4C is performed.

In addition, at the same time, the holding piece parts 17 and 17 of the fixing member 12C are latched onto the latching part 8b of the latching protrusion 8 of the bezel 3 from the outer side, and uplift of the back chassis 4C from the panel module 11 is prevented.

In a state in which the fixing member 12C is inserted into the space and the tip end of the engagement part 20 is latched onto the tip end part of the root part 8a, the third surface part 23 of the fixing member 12C is in surface contact with the attachment surface part 9c of the back chassis 4C.

Next, the shaft part 22d of the attachment member 22C is inserted into the screw insertion hole 19 of the fixing member 12C and screwed into the screw hole 9b of the back chassis 4C (refer to FIG. 24). At this time, the shaft part 22d of the attachment member 22C slides along the pressable part 21 of the fixing member 12C.

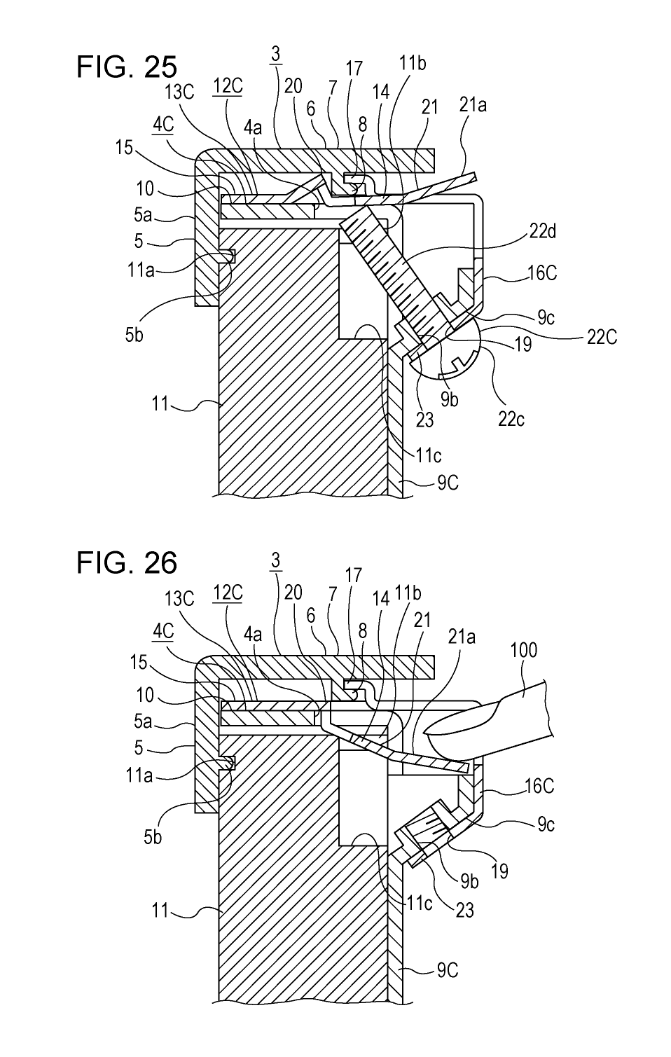

Furthermore, as the shaft part 22d of the attachment member 22C is screwed into the screw hole 9b, a pressing force is applied to the pressable part 21 in a direction which approaches the peripheral surface part 6 of the bezel 3 by the shaft part 22d of the attachment member 22C, and the deformed part 14 is elastically deformed with respect to the base part 13C (refer to FIG. 25). Additionally, since the shaft part 22d that is screwed into the screw hole 9b is inserted into the second relief concave part 11c of the panel module 11 from the screw hole 9b, contact between the shaft part 22d and the panel module 11 is avoided.

The engagement part 20 is deformed due to the deformed part 14 being elastically deformed, and is engaged with the latching protrusion 8 of the bezel 3. Therefore, a state in which dropout of the fixing member 12C from the bezel 3 is prevented, is attained, and at the same time, the fixing member 12C is attached to the back chassis 4C by the attachment member 22C, and the back chassis 4C is fixed to the bezel 3 by the fixing member 12C.

In the manner described above, the fixing member 12C has the first surface part 15 in which the base part 13C is continuous with the deformed part 14 and the third surface part 23 that has a different angle with respect to the first surface part 15, and the third surface part 23 is attached to the back chassis 4C, which is the first member, by the attachment member 22C.

Therefore, in the fixing member 12C, by forming a portion (the first surface part 15) in which the deformed part 14 is provided and a portion (the third surface part 23) which is attached to the back chassis 4C independently, it is possible to secure high functionality in the fixing member 12C without portions that have different functions interfering with one another.

In addition, when the screw member is used as the attachment member 22C, and the attachment member 22C is attached to the back chassis 4C, the attachment member 22C slides along the pressable part 21 and the pressable part 21 is elastically deformed.

Therefore, the attachment of the attachment member 22C to the back chassis 4C and the engagement of the engagement part 20 with the bezel 3 are performed at the same time as the fastening work of the attachment member 22C is performed, and it is possible to achieve an improvement in workability and a reduction in the number of parts.

Furthermore, since the deformed part 14 is elastically deformed by the shaft part 22d of the screw member, which is provided as the attachment member 22C, sliding along the pressable part 21, the deformed part 14 is elastically deformed by performing the fastening work of the attachment member 22C and it is possible to reliably perform elastic deformation of the deformed part 14 with simple work.

Additionally, in the display apparatus 1, in a case in which maintenance of each part or the like is being performed, there are cases in which it is necessary for the fixing member 12C to be detached from the back chassis 4C and the bezel 3. In such cases, a pressing force is applied to the pressable part 21 in a direction in which the pressable part 21 approaches the panel module 11 by a finger 100 in a state in which the attachment member 22C is detached from the back chassis 4C (refer to FIG. 26). By applying a pressing force to the pressable part 21 in a direction in which the pressable part 21 approaches the panel module 11 with a finger 100, the engaged state of the engagement part 20 with respect to the latching protrusion 8 is released, and it is possible to detach the fixing member 12C from a space between the latching protrusion 8 and the outer peripheral surface part 10 by drawing the fixing member 12C out toward the rear.

In this manner, since the pressable part 21 functions as a lever when performing release of the engagement part 20 with respect to the bezel 3, it is possible to easily perform detachment work of the fixing member 12C and it is possible to achieve a reduction in the number of parts without having to provide a separate lever solely for release.

### Overview

In the manner described above, in the display apparatus 1, in the fixing members 12, 12A, 12B and 12C, the deformed part 14 is elastically deformed, the engagement part 20 engages bezel 3, which is the second member, and the back chassis 4 or 4C is fixed to the bezel 3 due to a pressing force being applied to the pressable part 21 by the attachment member 22, 22A or 22C.

Therefore, since the engagement part 20 is engaged with the bezel 3 by the attachment member 22, 22A or 22C, the back chassis 4 or 4C is fixed to the bezel 3, and the panel module 11 is held against the bezel 3, it is possible to achieve an improvement in the workability of the fixing work.

In addition, since the engagement part 20 is elastically deformed and engaged with the latching protrusion of the bezel 3, a sufficient engagement amount of the engagement part 20 with the latching protrusion 8 is secured in the fixed state, and it is possible to secure a stable fixed state of the back chassis 4 or 4C with respect to the bezel 3.

Furthermore, since the fixing member 12, 12A, 12B or 12C is inserted into a space between the latching protrusion 8 and the outer peripheral surface part 10 in a state before the deformed part 14 is elastically deformed, it is possible to secure smooth insertion of the fixing member 12, 12A, 12B or 12C, and it is possible to secure high workability in the fixing work.

In addition, since the fixing member 12, 12A, 12B or 12C is inserted into a space between the latching protrusion 8 and the outer peripheral surface part 10 in a state before the deformed part 14 is elastically deformed, the fixing work is performed and the fixing member 12, 12A, 12B or 12C is not positioned on the outside of the bezel 3, it is possible to achieve miniaturization of the display apparatus 1 in which the outer shape of the display apparatus 1 is reduced by the size of the fixing member 12, 12A, 12B or 12C.

### Other Variations

In the abovementioned description, an example in which the back chassis 4 that is provided as the first member is fixed to the bezel 3 that is provided as the second member by the fixing member 12, 12A, 12B or 12C, but the first member may be a member other than the back chassis 4.

For example, a configuration in which the panel module 11 is provided as the first member, and the panel module 11 is fixed to the bezel 3 by the fixing member 12, 12A, 12B or 12C may be used. In this case, the back chassis 4 is attached to a predetermined member in a state in which the back chassis 4 does not contribute to the attachment of the panel module 11 to the bezel 3.

Additionally, in a case in which the panel module 11 is fixed to the bezel 3 by the fixing member 12, 12A, 12B or 12C, positioning protruding parts, which are inserted into the positioning hole 18 of the fixing member 12, 12A, 12B or 12C are provided, and a screw hole, into which the attachment member 22 or the like is screwed, is formed in the panel module 11.

### Present Disclosure

It is possible for the embodiments of the present disclosure to have the following configurations.

(1) A fixing member including a base part that is attached to a first member by an attachment member, and a deformed part, which is elastically deformable with respect to the base part and has an engagement part that is capable of engaging a second member and a pressable part to which a pressing force is applied by the attachment member, in which the deformed part is elastically deformed, the engagement part engages the second member and the first member is fixed to the second member due to a pressing force being applied to the pressable part by the attachment member when the base part is attached to the first member by the attachment member.

(2) The fixing member according to (1), in which the base part is configured by a first surface part that is continuous with the deformed part and a second surface part that is orthogonal to the first surface part, and the second surface part is attached to the first member by the attachment member.

(3) The fixing member according to (1) or (2), in which a screw member is used as the attachment member, and the deformed part is elastically deformed by a part of the screw member sliding along the pressable part when the screw member is fastened to the first member.

(4) The fixing member according to any one of (1) to (3), in which the screw member is formed from a shaft part that has thread grooves and a head part that is provided at one end of the shaft part in the direction of the shaft, and the deformed part is elastically deformed by the head part sliding along the pressable part.

(5) The fixing member according to any one of (1) to (4), in which the pressable part functions as a lever that releases the engagement of the engagement part with the second member.

(6) The fixing member according to any one of (1) to (5), in which a tip end part of the pressable part is provided as a guide part that is inclined with respect to other portions and along which the head part of the screw member slides.

(7) A display apparatus including a panel module that has a display that displays images, a bezel that holds a peripheral part of the panel module, a back chassis that presses the panel module and is pressed against the bezel and a fixing member that fixes the back chassis to the bezel, in which the fixing member includes a base part that is attached to the back chassis by an attachment member and a deformed part, which is elastically deformable with respect to the base part and has an engagement part that is capable of engaging the bezel and a pressable part to which a pressing force is applied by the attachment member, and the deformed part is elastically deformed, the engagement part engages the bezel and the back chassis is fixed to the bezel due to a pressing force being applied to the pressable part by the attachment member when the base part is attached to the back chassis by the attachment member.

(8) A display apparatus including a panel module that has a display that displays images, a bezel that holds a peripheral part of the panel module and a fixing member that fixes a back chassis to the bezel, in which the fixing member includes a base part that is attached to the panel module by an attachment member and a deformed part, which is elastically deformable with respect to the base part and has an engagement part that is capable of engaging the bezel and a pressable part to which a pressing force is applied by the attachment member, and the deformed part is elastically deformed, the engagement part engages the bezel and the panel module is fixed to the bezel due to a pressing force being applied to the pressable part by the attachment member when the base part is attached to the panel module by the attachment member.

The specific forms and structures of each part shown in the preferable embodiments for implementing the abovementioned disclosure merely indicate materializations when implementing the embodiments according to the present disclosure by way of example and are not intended to limit the technical scope of the embodiments according to the present disclosure.

The present disclosure contains subject matter related to that disclosed in Japanese Priority Patent Application JP 2012-193794 filed in the Japan Patent Office on Sep. 4, 2012, the entire contents of which are hereby incorporated by reference.

What is claimed is:

1. A fixing member comprising:
a base part that is attached to a first member by an attachment member; and
a deformed part, which is elastically deformable with respect to the base part and has an engagement part that is capable of engaging a second member and a pressable part to which a pressing force is applied by the attachment member,
wherein the deformed part is elastically deformed, the engagement part engages the second member and the first member is fixed to the second member due to a pressing force being applied to the pressable part by the attachment member when the base part is attached to the first member by the attachment member.

2. The fixing member according to claim 1,
wherein the base part is configured by a first surface part that is continuous with the deformed part and a second surface part that is orthogonal to the first surface part, and
the second surface part is attached to the first member by the attachment member.

3. The fixing member according to claim 1,
wherein a screw member is used as the attachment member, and
the deformed part is elastically deformed by a part of the screw member sliding along the pressable part when the screw member is fastened to the first member.

4. The fixing member according to claim 3,
wherein the screw member is formed from a shaft part that has thread grooves and a head part that is provided at one end of the shaft part in the direction of the shaft, and
the deformed part is elastically deformed by the head part sliding along the pressable part.

5. The fixing member according to claim 1,
wherein the pressable part functions as a lever that releases the engagement of the engagement part with the second member.

6. The fixing member according to claim 4,
wherein a tip end part of the pressable part is provided as a guide part that is inclined with respect to other portions and along which the head part of the screw member slides.

7. A display apparatus comprising:
a panel module that has a display that displays images;
a bezel that holds a peripheral part of the panel module;
a back chassis that presses the panel module and is pressed against the bezel; and
a fixing member that fixes the back chassis to the bezel,
wherein the fixing member includes
a base part that is attached to the back chassis by an attachment member, and
a deformed part, which is elastically deformable with respect to the base part and has an engagement part that is capable of engaging the bezel and a pressable part to which a pressing force is applied by the attachment member, and
the deformed part is elastically deformed, the engagement part engages the bezel and the back chassis is fixed to the bezel due to a pressing force being applied to the pressable part by the attachment member when the base part is attached to the back chassis by the attachment member.

8. A display apparatus comprising:
a panel module that has a display that displays images;
a bezel that holds a peripheral part of the panel module; and
a fixing member that fixes a back chassis to the bezel, wherein the fixing member includes
a base part that is attached to the panel module by an attachment member, and
a deformed part, which is elastically deformable with respect to the base part and has an engagement part that is capable of engaging the bezel and a pressable part to which a pressing force is applied by the attachment member, and
the deformed part is elastically deformed, the engagement part engages the bezel and the panel module is fixed to the bezel due to a pressing force being applied to the pressable part by the attachment member when the base part is attached to the panel module by the attachment member.
